(19) United States
(12) Patent Application Publication
(10) Pub. No.: US 2007/0041487 A1
(43) Pub. Date: Feb. 22, 2007

(54) Method and system for a digital frequency divider

(76) Inventor: Karapet Khanoyan, Lake Forest, CA (US)

Correspondence Address: MCANDREWS HELD & MALLOY, LTD, 500 WEST MADISON STREET, SUITE 3400, CHICAGO, IL, 60661, US

(21) Appl. No.: 11/207,208

(22) Filed: Aug. 16, 2005

(51) Int. Cl. H03K 23/00

(52) U.S. Cl. 377/48

(57) ABSTRACT

A digital frequency divider divides an input signal by a factor value specified as an N+1 bit value, utilizing a plurality of counter having a total of N bits. A single count value is generated based on a number of cycles of the input signal and a single generated count value compared with the factor value to generate a match signal comprising a pipelined match signal. The comparison may be performed utilizing a pipelined count value. An output signal from the digital frequency divider is toggled utilizing the match signal. The digital frequency dividing is performed utilizing at least one comparator and one counter for handling lower-order bits, and at least one comparator and one counter for handling higher-order bits. One bit of the factor value, and the output signal, is utilized to select one of two clock signals, which may be utilized to toggle the output signal.

### RELATED APPLICATIONS

This application makes reference to U.S. patent application Ser. No. ______ (Attorney Docket Number 16568US01) filed Aug. 16, 205.

The above stated application is hereby incorporated herein by reference in its entirety.

### FEDERALLY SPONSORED RESEARCH OR DEVELOPMENT

[Not Applicable]

### MICROFICHE/COPYRIGHT REFERENCE

[Not Applicable]

### FIELD OF THE INVENTION

Certain embodiments of the invention relate to generating electrical signals. More specifically, certain embodiments of the invention relate to a method and system for a digital frequency divider.

### BACKGROUND OF THE INVENTION

High-speed digital communication networks over copper and optical fiber are used in many network communication and digital storage applications. Ethernet and Fiber Channel are two widely used communication protocols, which continue to evolve in response to increasing demands for higher bandwidth in digital communication systems. The Ethernet protocol may provide collision detection and carrier sensing in the physical layer of the OSI reference model. The physical layer, layer 1, is responsible for handling all electrical, optical, opto-electrical and mechanical requirements for interfacing to the communication media. Notably, the physical layer may facilitate the transfer of electrical signals representing an information bitstream. The physical layer (PHY) may also provide services such as, encoding, decoding, synchronization, clock data recovery, and transmission and reception of bit streams. Some PHY services may be provided by one or more Ethernet PHY transceivers.

As the demand for higher data rates and bandwidth continues to increase, equipment vendors are continuously being forced to employ new design techniques for manufacturing network equipment capable of handling these increased data rates. In response to this demand, physical layer (PHY) transceivers have been designed to operate at gigabit speeds to keep pace with this demand for higher data rates. Gigabit Ethernet, which initially found application in gigabit servers, is becoming widespread in personal computers, laptops, and switches, thereby providing the necessary infrastructure for handling data traffic of PCs and packetized telephones. At gigabit speeds, generation of clocks of different frequencies for use by the gigabit Ethernet transceiver is central to the operation of the transceiver. This is particularly true for phase locked loop circuits implemented in the transceiver. In this regard, gigabit Ethernet transceivers may be adapted to utilize one or more digital frequency dividers for the creation of one or more clocks within the integrated circuit. A digital frequency divider may be utilized to accept a high-frequency input clock signal and generate a lower-frequency clock whose frequency is an integer factor of the input clock.

Conventional digital frequency dividers, however, may utilize multiple comparators, increasing the capacitive loading on the counter circuit in the circuit's critical signal path. Conventional digital frequency dividers may utilize N-bit counters to achieve a digital frequency division factor of 2ˆN, increasing the complexity associated with adding the N-th bit to the counter circuit in the circuit critical path. Conventional digital frequency dividers may not pipeline signals along the critical signal path, or the longest signal timing path within the digital frequency divider. These features of conventional digital frequency dividers may significantly decrease the maximum input clock frequency that the digital frequency divider can utilize.

Further limitations and disadvantages of conventional and traditional approaches will become apparent to one of skill in the art, through comparison of such systems with the present invention as set forth in the remainder of the present application with reference to the drawings.

### BRIEF SUMMARY OF THE INVENTION

A system and/or method for a digital frequency divider, substantially as shown in and/or described in connection with at least one of the figures, as set forth more completely in the claims.

Various advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram of an exemplary integrated circuit system with phase locked loop, which may be utilized in accordance with an embodiment of the invention.

FIG. 2A is a block diagram of an exemplary digital frequency divider, in accordance with an embodiment of the invention.

FIG. 2B is a block diagram of an exemplary digital frequency divider, in accordance with an embodiment of the invention.

FIG. 2C is a block diagram of an exemplary digital frequency divider control block, which may be utilized in accordance with an embodiment of the invention.

FIG. 3 is a block diagram of an exemplary digital frequency divider fixed counter block, which may be utilized in accordance with an embodiment of the invention.

FIG. 4 is a block diagram of an exemplary digital frequency divider fixed comparator block, which may be utilized in accordance with an embodiment of the invention.

FIG. 5 is a block diagram of an exemplary digital frequency divider scalable counter block, which may be utilized in accordance with an embodiment of the invention.

FIG. 6 is a block diagram of an exemplary digital frequency divider scalable comparator block, which may be utilized in accordance with an embodiment of the invention.

FIG. 7 is a block diagram of the exemplary digital frequency divider counter reset and output generation block , which may be utilized in accordance with an embodiment of the invention.

FIG. 8 is a flow diagram of exemplary steps for digitally generating frequency divided output signals, in accordance with an embodiment of the invention.

### DETAILED DESCRIPTION OF THE INVENTION

Certain embodiments of the invention may be found in a method and system for a digital frequency divider. In one aspect of the invention, a digital frequency divider may be implemented with fewer comparator blocks than other digital frequency dividers and operates at higher clock frequencies. The digital frequency divider may double the frequency programmability range of other digital frequency dividers without having to increase the total number of counter bits by an additional bit. In another aspect of the invention, the digital frequency divider is partitioned into fixed blocks and scalable blocks. The maximum frequency division factor can be increased or decreased by modifying only the scalable blocks. This allows the same fixed blocks to be reused without modification in digital frequency dividers of various frequency division factors. The digital frequency divider disclosed herein may also utilize various registers to pipeline signals and interrupt critical timing paths.

A digital frequency divider implemented according to an embodiment of the invention may contribute to a reduction in the silicon area required to implement an integrated circuit or chip. For example, the digital frequency divider may utilize a reduced number of integrated circuit (IC) components such as gates compared to other digital frequency dividers. The reduced number of IC components results such as the gates and comparator blocks results in reduced power consumption when compared to other frequency dividers.

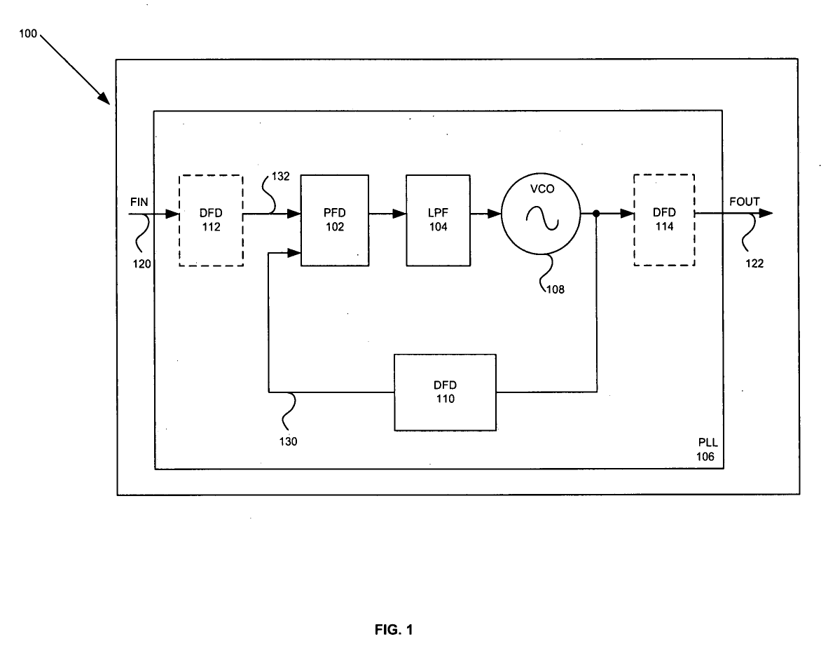

FIG. 1 is a block diagram of an exemplary integrated circuit system with phase locked loop, which may be utilized in accordance with an embodiment of the invention. Referring to FIG. 1, the exemplary integrated circuit (IC) system 100 may comprise a phase locked loop 106. The phase locked loop 106 may comprise phase frequency detect (PFD) block 102, loop filter (LPF) block 104, VCO block 108, and digital frequency dividers (DFD) 110, 112, and 114. An output of digital frequency divider (DFD) 112 may be coupled to an input of the PFD 102 and an output of the PFD 102 may be coupled to an input of the LPF 104. An output of the LPF 104 may be coupled to an input of the VCO 108 and an output of the VCO 108 may be coupled to an input of the digital frequency divider (DFD) 114 and an input of the digital frequency divider (DFD) 110. An output of the digital frequency divider (DFD) 110 may also be coupled to an input of the PFD 102.

The phase frequency detect (PFD) block 102 may comprise suitable logic and/or circuitry that may be adapted to compare the frequencies of two periodic input signals, and generate an output that reflects the phase and/or frequency difference between the two input signals.

The loop filter block (LPF) 104 may comprise suitable logic and/or circuitry that may be adapted to filter and amplify an input signal and generate a voltage signal suitable for use by a voltage controlled oscillator.

The voltage control oscillator (VCO) block 108 may comprise suitable logic and/or circuitry that may be adapted to accept a voltage input and produce a periodic output signal.

The digital frequency dividers (DFD) 110, 112, and 114 may comprise suitable logic and/or circuitry that may be adapted to accept a periodic input signal and produce an output whose frequency is a factor of the input signal frequency.

In operation, the PLL block 106 within the IC 100 may generate a periodic output clock (FOUT) 122 which may be coupled to inputs of other logic in the integrated circuit (IC) 100 or may be an output of the integrated circuit (IC) 100. The input signal FIN 120 received by the PLL block 106 may be divided in frequency by the digital frequency divider (DFD) block 112 to generate a divided input signal 132. The phase frequency detect (PFD) block 102 may compare the frequency and phase of the divided input signal 132 with the output of the digital frequency divider (DFD) block 110, and may produce an output signal which is a result of the comparison. The output of the phase frequency detect (PFD) block 102 may be filtered and amplified by the loop filter (LPF) 104, to produce a voltage output that may be used by voltage controlled oscillator (VCO) block 108 to produce a periodic output.

The output of voltage controlled oscillator (VCO) block 108 may be divided in frequency by the digital frequency divider (DFD) block 110 to produce the divided VCO output 130, and fed back to the phase frequency detect (PFD) block 102. In operation, the filtered output of the phase frequency detect (PFD) block 102 may adjust the output of the voltage controlled oscillator (VCO) block 108 to eliminate any phase and/or frequency differences that may exist between the divided VCO output 130 and the divided input 132. When the. differences in the phase and/or the frequency occur, the PLL 106 may be said to be in a “locked” condition. The output of the voltage controlled oscillator (VCO) block 108 may be divided in frequency by the digital frequency divider (DFD) block 114 to produce a periodic output clock (FOUT) 122. The periodic output clock (FOUT) 122 may be the output of the PLL block 106, and that may be coupled to inputs of other logic in the integrated circuit (IC) 100 or may be an output of the integrated circuit (IC) 100. The digital frequency divider (DFD) blocks 110, 112, 114 may be used to adjust the frequency relationship between the PLL input FIN 120 and the PLL output FOUT 122.

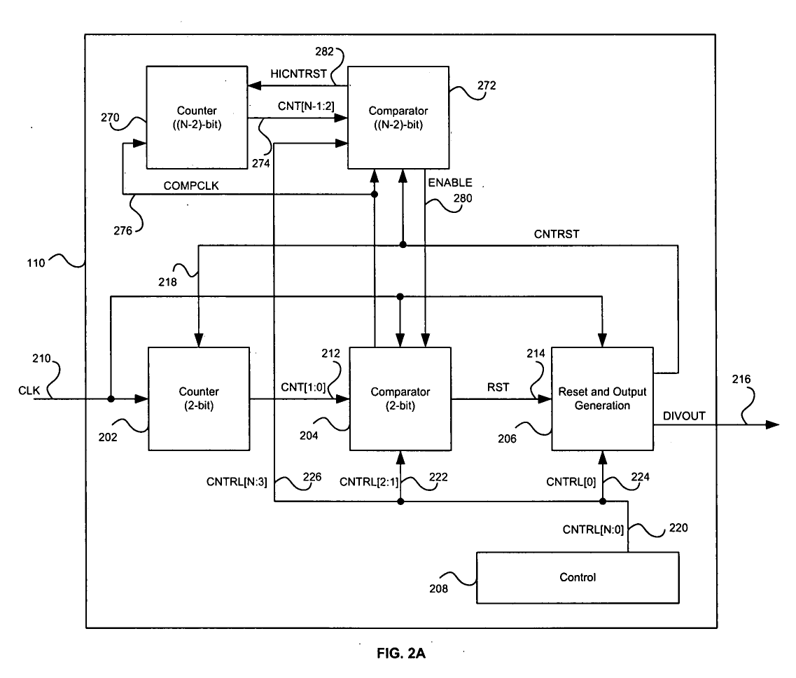

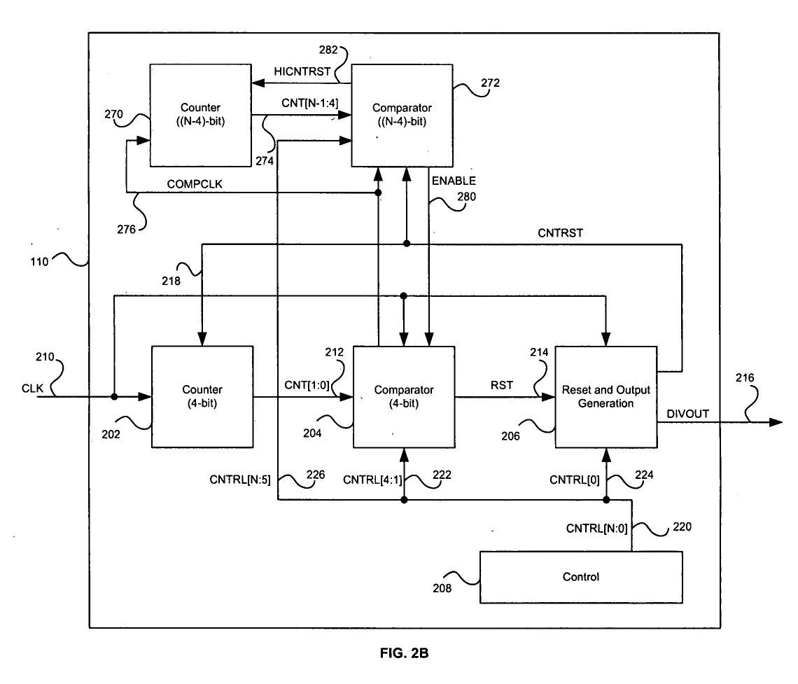

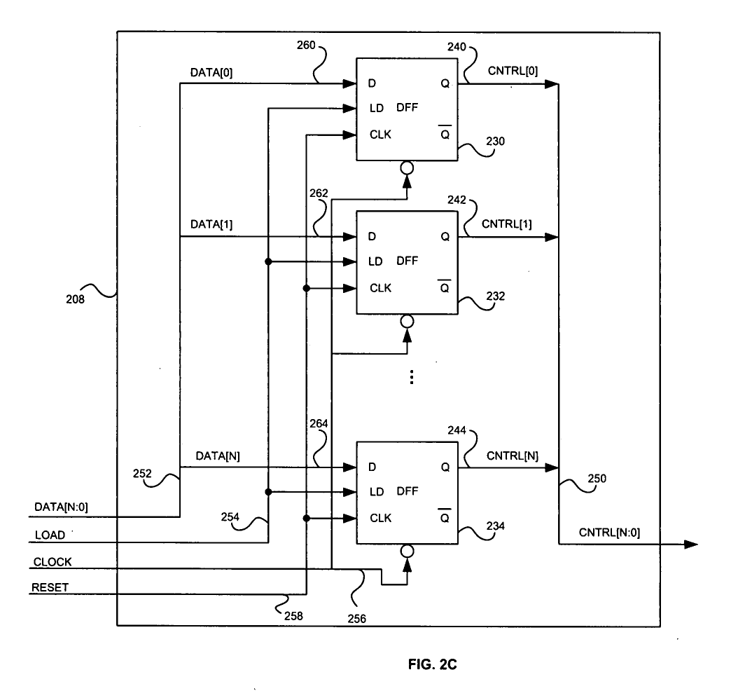

FIG. 2A is a block diagram of an exemplary digital frequency divider 110 of FIG. 1, in accordance with an embodiment of the invention. Referring to FIG. 2A, the exemplary digital frequency divider 110 may comprise a control block 208, a fixed counter block 202, a scalable counter block 270, a fixed comparator block 204, a scalable comparator block 272, and a counter reset and output generation block 206. The control block 208 may be coupled to an input of the fixed comparator block 204, an input of the scalable comparator block 272, and an input of the counter reset and output generation block 206. An output of the fixed counter block 202 may be coupled to an input of the fixed comparator block 204. An output of the scalable comparator block 272 may be coupled to an input of the fixed comparator block 204. An output of the fixed comparator block 204 may be coupled to an input of the counter reset and output generation block 206. Another output of the fixed comparator block 204 may be coupled to an input of the scalable comparator block 272 and to an input of the scalable counter block 270.

An output of the scalable comparator block 272 may be coupled to an input of the scalable counter block 270. An output of the scalable counter block 270 may be coupled to an input of the scalable comparator block 272. An input clock signal (CLK) 210 is coupled to the fixed counter block 202, the fixed comparator block 204, and the counter reset and output generation block 206. An output of the counter reset and output generation block 206 may be coupled to an input of the fixed counter block 202, and an input of the scalable comparator block 272. A frequency divided output signal (DIVOUT) 216 may be coupled to the counter reset and output generation block 206.

The control block 208 may comprise suitable logic and/or circuitry that may be adapted to store a plurality of control or configuration values, that may be presented on the output control bus (CNTRL[N:0]) 220. In one embodiment of the invention, the control block 208 may store (N+1) bits of control or configuration values. Further details of the control block 208 are illustrated in FIG. 2C. In an embodiment of the invention, the control block 208 may comprise suitable circuitry, logic, and/or code and may be adapted to store a plurality of control or configuration values, which may be presented on an output control bus. The configuration values may be updated using an input data bus when a load signal is asserted for at least one cycle of the clock 256, and the reset 256 is de-asserted.

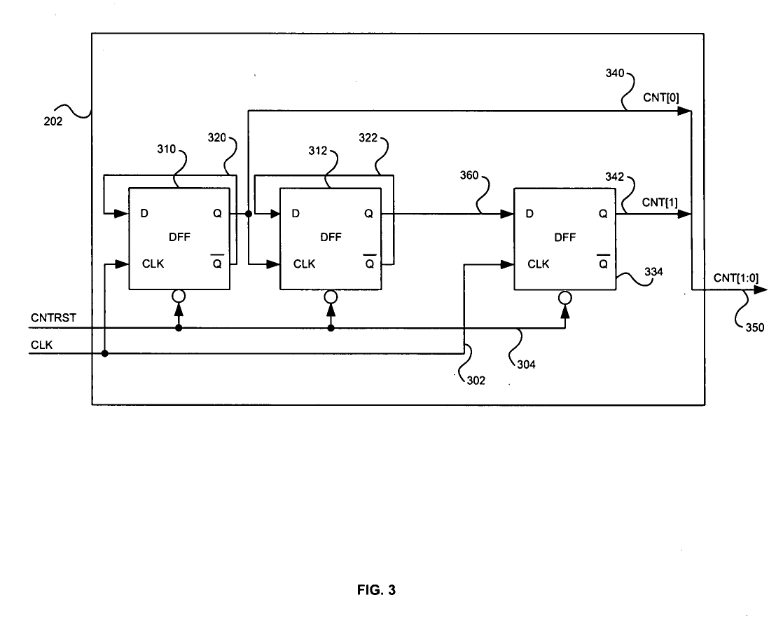

The fixed counter block 202 may comprise suitable logic and/or circuitry that may be adapted to receive a clock (CLK) 210 and counter reset (CNTRST) 218 inputs, and for each cycle of the clock (CLK) 210 where the counter reset (CNTRST) 218 is de-asserted, increment an 2-bit count value presented on the counter output CNT[1:0] 212, and when the counter reset (CNTRST) 218 is asserted, present a determined reset value on the counter output CNT[1:0] 212. Further details of the fixed counter block 202 are illustrated in FIG. 3. In one embodiment of the invention, the fixed counter block 202 may be a 2-bit counter. The fixed counter block 202 may be adapted to receive an input clock signal (CLK) 210 and generate an output count signal CNT[1:0] 212.

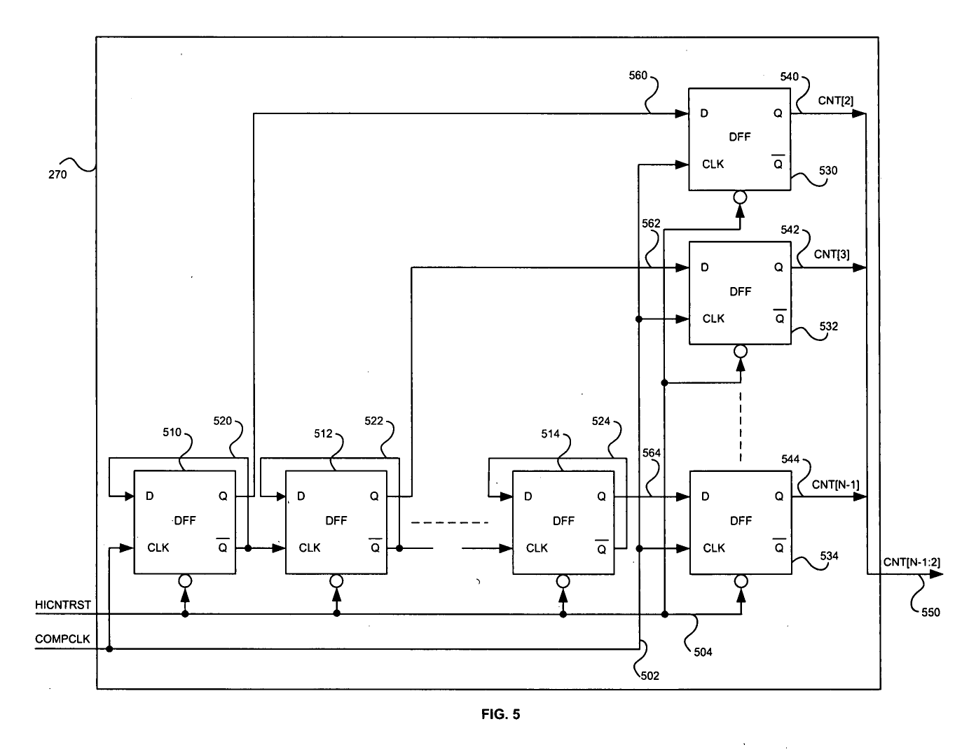

The scalable counter block 270 may comprise suitable logic and/or circuitry that may be adapted to receive a clock (COMPCLK) 276 and counter reset (HICNTRST) 282 inputs, and for each cycle of the clock (COMPCLK) 276 where the counter reset (HICNTRST) 282 is de-asserted, increment an N−2 bit count value presented on the counter output CNT[N−1:2] 274, and when the counter reset (HICNTRST) 282 is asserted, present a determined reset value on the counter output CNT[N−1:2] 274. Further details of the scalable counter block 270 are illustrated in FIG. 5. In one embodiment of the invention, the scalable counter block 270 may be an N−2 bit counter. The scalable counter block 270 may be adapted to receive an input clock signal (COMPCLK) 276 and generate an output count signal CNT[N−1:2] 274.

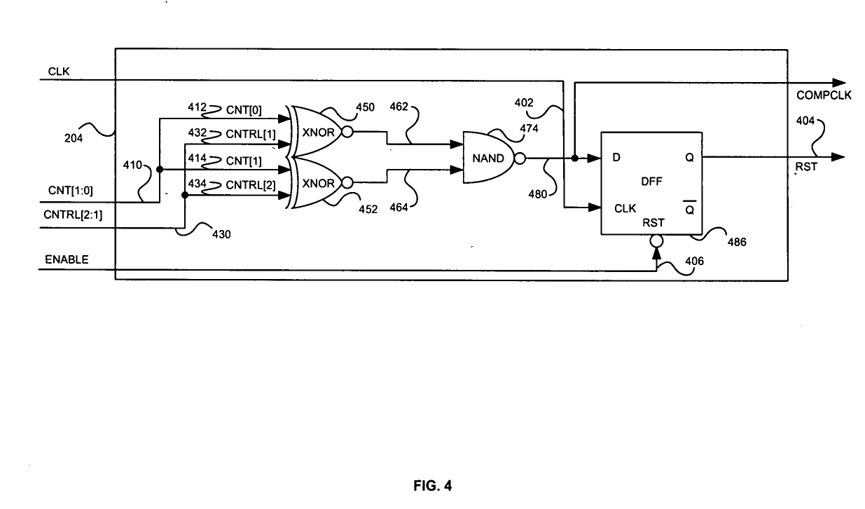

The fixed comparator block 204 may comprise suitable logic and/or circuitry that may be adapted to compare an 2-bit count value (CNT[1:0]) 212 with an 2-bit control value (CNTRL[2:1]) 222, and assert an output comparison result signal (RST) 214, that may be delayed by one or more cycles of the clock (CLK) 210, when the 2-bit count value (CNT[1:0]) 212 and the 2-bit control value (CNTRL[2:1]) 222 are identical and the enable signal (ENABLE) 280 is asserted. Further details of the fixed comparator block 204 are illustrated in FIG. 4. In an embodiment of the invention, the fixed comparator block 204 may compare two 2-bit values, and assert a comparison result output if the values are identical, and the enable signal is asserted. The fixed comparator block 204 may be adapted to receive a count signal CNT[1:0] generated by the fixed counter block 202 and generate an output reset signal (RST) 214. The fixed comparator block 204 may also be adapted to receive as an input a control signal CNTRL[2:1], which is generated by the control block 208. The fixed comparator block 204 may also be adapted to receive as an input, an enable signal (ENABLE) 280, which is generated by the scalable comparator block 272. The clock signal (CLK) 210 may also be provided as an input to the fixed comparator block 204.

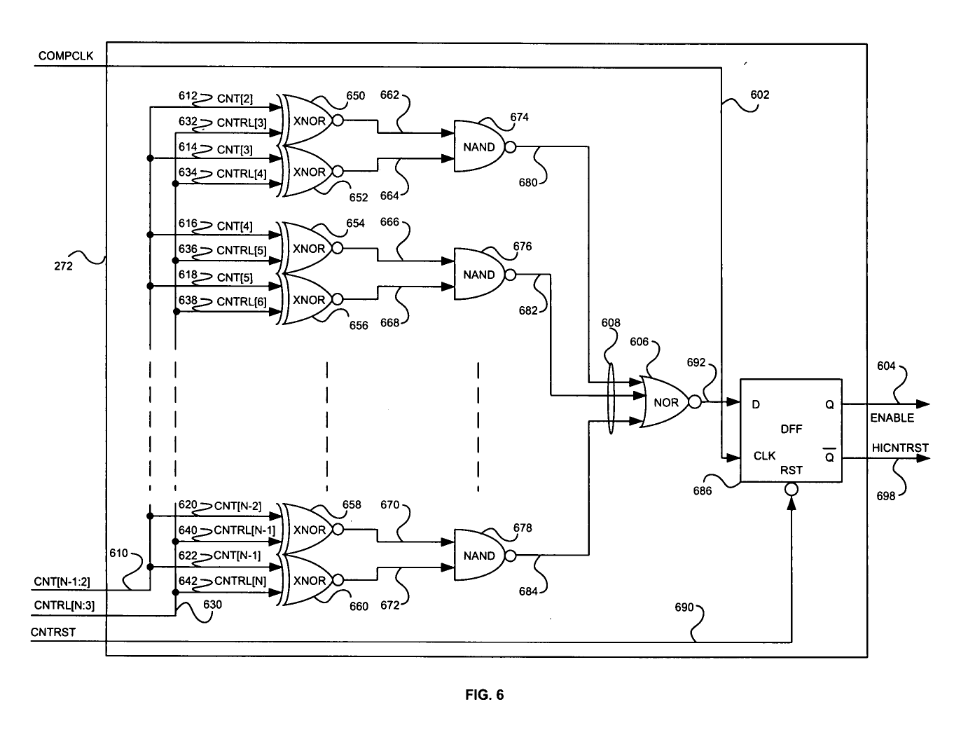

The scalable comparator block 272 may comprise suitable logic and/or circuitry that may be adapted to compare an N−2 bit count value (CNT[N−1:2]) 274 with an N−2 bit control value (CNTRL[N:3]) 226, and assert an output comparison result signal (ENABLE) 280 and a reset output signal (HICNTRST) 282, which may be delayed by one or more cycles of the clock (COMPCLK) 276, when the N−2 bit count value (CNT[N−1:2]) 274 and the N−2 bit control value (CNTRL[N:3]) 226 are identical. Further details of the scalable comparator block 272 are illustrated in FIG. 6. In an embodiment of the invention, the scalable comparator block 272 may compare two N−2 bit values, and assert a comparison result output in instances where the two values are identical. The scalable comparator block 272 may be adapted to receive a count signal CNT[N−1:2] generated by the scalable counter block 270 and generate an output enable signal (ENABLE) 280 and a reset output signal (HICNTRST) 282. The scalable comparator block 204 may also be adapted to receive as an input a control signal CNTRL[N:3], which is generated by the control block 208. The clock signal (COMPCLK) 276 may also be provided as an input to the scalable comparator block 272.

The counter reset and output generation block 206 may comprise suitable logic and/or circuitry that may be adapted to generate a counter reset signal CNTRST 218. Further details of the counter reset and output generation block 206 are illustrated in FIG. 5. The counter reset signal CNTRST 218 may be utilized to reset the fixed counter block 202, and may be utilized by the scalable comparator block 272. The counter reset and output generation block 206 may also be adapted to receive as an input the reset signal RST 214, which is generated as an output of the fixed comparator block 204. The counter reset and output generation block 206 may be adapted to reset the fixed counter block 202. The clock signal (CLK) 210 may also be provided as an input to the fixed comparator block 204. The counter reset and output generation block 206 may generate a frequency divided output signal (DIVOUT) 216.

The output control bus (CNTRL[N:0]) 220 of the control block 208 may be used to control the operation of the fixed comparator block 204. The fixed comparator block 204 may accept 2-bits of the output control bus (CNTRL[N:0]) 220. The fixed comparator block 204 may compare the 2-bit control input (CTRL[2:1]) 222 with the 2-bit input from the fixed counter block 202, and may assert an output comparison result signal (RST) 214 if the two 2-bit inputs 220 and 222 are identical. When a different value of 2-bit control input (CTRL[2:1]) 222 is used, the fixed comparator block 204 asserts output comparison result signal (RST) 214 at a corresponding different value of the N-bit count value (CNT[1:0]) 212. In an embodiment of the invention, the 2-bit control input (CTRL[2:1]) 222 is generated utilizing bits [2:1] of output control bus (CNTRL[N:0]) 220.

The output control bus (CNTRL[N:0]) 220 of the control block 208 may be used to control the operation of the scalable comparator block 272. The scalable comparator block 272 may accept N−2 bits of the output control bus (CNTRL[N:0]) 220. The scalable comparator block 272 may compare the N−2 bit control input (CTRL[N:3]) 226 with the N−2 bit input from the scalable counter 270, and may assert an output comparison result signal (ENABLE) 280 in instances where the two N−2 bit inputs 274 and 226 are identical. When a different value of N−2 bit control input (CTRL[N:3]) 226 is used, the scalable comparator block 272 may assert an output comparison result signal (ENABLE) 280 at a corresponding different value of the N−2 bit count (CNT[N−1:2]) 274. In an embodiment of the invention, the N−2 bit control input (CTRL[N:3]) 226 may be generated utilizing bits [N:3] of output control bus (CNTRL[N:0]) 220.

The output control bus (CNTRL[N:0]) 220 of the control block 208 may be used to control the operation of the counter reset and output generation block 206. When the control input (CTRL[0]) 224 de-asserted, the counter reset and output generation block 206 will generate a frequency divided output signal (DIVOUT) 216 that is an even frequency division of the input clock signal (CLK) 210. When the control input (CTRL[0]) 224 is asserted, the counter reset and output generation block 206 may generate a frequency divided output signal (DIVOUT) 216 that is an odd frequency division of the input clock signal (CLK) 210. In an embodiment of the invention, the control input (CTRL[0]) 224 is generated utilizing bit [0] of the output control bus (CNTRL[N:0]) 220.

In operation, the digital frequency divider block 110 receives an input clock signal (CLK) 210, and the count value (CNT[1:0]) 212 stored in the fixed counter block 202 may increment once per cycle of the input clock signal (CLK) 210 when the counter reset (CNTRST) 218 is de-asserted. The fixed comparator block 204 may transition a clock (COMPCLK) 276 from a de-asserted state to an asserted state when the count value (CNT[1:0]) 212 is identical to the determined 2-bit control value (CNTRL[2:1]) 222. The count value (CNT(N−1:2]) 274 stored in the scalable counter block 270 may increment once per cycle of the input clock signal (COMPCLK) 276 when the counter reset (HICNTRST) 282 is de-asserted. The scalable comparator block 272 may assert an output comparison result signal (ENABLE) 280 when the count value (CNT[N−1:2]) 274 is identical to the determined N−2 bit control value (CNTRL[N:3]) 226. The fixed comparator block 204 may assert an output comparison result signal (RST) 214 when the count value (CNT[1:0]) 212 is identical to the determined 2-bit control value (CNTRL[2:1]) 222, and the output comparison result signal (ENABLE) 280 is asserted. Therefore, the output comparison result signal (RST) 214 may be asserted if the higher-order count value bits CNT(N−1:2] 274 are identical to the higher-order control word bits CNTRL[N:3] 226, and the lower-order count value bits CNT[1:0] 212 are identical to the lower-order control word bits CNTRL[2:1] 222. The reset and output generation block may detect the assertion of the output comparison result signal (RST) 214 and may assert the counter reset (CNTRST) 218 output. The reset and output generation block may detect the assertion of the output comparison result signal (RST) 214 and may toggle the frequency divided output signal (DIVOUT) 216. The fixed counter block 202 may reset to a determined value when the counter reset (CNTRST) 218 input is asserted, and may resume counting. The scalable comparator block 272 may detect the assertion of the counter reset (CNTRST) 218, and may assert the counter reset (HICNTRST) 282. The scalable counter block 270 may reset to a determined value when the counter reset (HICNTRST) 282 input is asserted, and may resume counting.

Even though FIG. 2A illustrates an exemplary digital frequency divider comprising a 2-bit fixed counter block 202, a 2-bit fixed comparator block 204, an N−2-bit scalable counter block 270, and an N−2 bit scalable comparator block 272, the invention may not be so limited. The fixed counter block 202 may comprise an X-bit counter, and the fixed comparator block 204 may compare two X-bit values, where N>X>1. Additionally, the assignment of the bits as shown are for illustrative purposes and as a result, the invention is not so limited. Accordingly, other bit assignments may be utilized.

The fixed counter block 202 may be adapted to count through the lower-order X bits of a N-bit count value, where the count value 212 may comprise bits [X−1:0] of the N-bit count value. The scalable counter block 270 may be adapted to count through the higher-order X-bits of a N-bit count value, where the count value 274 may comprise bits [N−1:X] of the N-bit count value.

The fixed comparator block 204 may compare the lower-order X bits of a N-bit count value, where the count value 212 may comprise bits [X−1:0] of the N-bit count value, with the lower-order X bits of an N-bit control word slice, where the control word 222 may comprise bits [X:1] of the N+1 bit control word (CNTRL[N:0]) 220. The scalable comparator block 272 may compare the higher-order N-X bits of a N-bit count value, where the count value 274 may comprise bits [N−1:X] of the N-bit count value, with the higher-order N-X bits of an N-bit control word slice, where the control word 226 may comprise bits [N:X+1] of the N+1 bit control word (CNTRL[N:0]) 220.

FIG. 2B is a block diagram of an exemplary digital frequency divider 110 of FIG. 1, in accordance with an embodiment of the invention. Referring to FIG. 2B, the exemplary digital frequency divider 110 may comprise a control block 208, a fixed counter block 202, a scalable counter block 270, a fixed comparator block 204, a scalable comparator block 272, and a counter reset and divider output block 206. In this embodiment of the invention, the fixed counter block 202 may be a 4-bit counter, and the scalable counter block 270 may be an N−4 bit counter. Additionally, the fixed comparator block 204 may compare two 4-bit values, and the scalable comparator block 272 may compare two N−4 bit values.

The control block 208 may be coupled to an input of the fixed comparator block 204, an input of the scalable comparator block 272, and an input of the counter reset and output generation block 206. An output of the fixed counter block 202 may be coupled to an input of the fixed comparator block 204. An output of the scalable comparator block 272 may be coupled to an input of the fixed comparator block 204. An output of the fixed comparator block 204 may be coupled to an input of the counter reset and output generation block 206. Another output of the fixed comparator block 204 may be coupled to an input of the scalable comparator block 272 and to an input of the scalable counter block 270.

An output of the scalable comparator block 272 may be coupled to an input of the scalable counter block 270. An output of the scalable counter block 270 may be coupled to an input of the scalable comparator block 272. An input clock signal (CLK) 210 is coupled to the fixed counter block 202, the fixed comparator block 204, and the counter reset and output generation block 206. An output of the counter reset and output generation block 206 may be coupled to an input of the fixed counter block 202, and an input of the scalable comparator block 272. A frequency divided output signal (DIVOUT) 216 may be coupled to the counter reset and output generation block 206.

FIG. 2C is a block diagram of an exemplary digital frequency divider control block 208 of FIG. 2A, which may be utilized in accordance with an embodiment of the invention. Referring to FIG. 2C, the control block 208 may comprise flip-flops 230, 232, . . . , 234. An input clock signal (CLOCK) 256 may be coupled to the flip-flops 230, 232, . . . , 234. A load enable signal (LOAD) 254 may be coupled to the flip-flops 230, 232, . . . , 234. A reset signal (RESET) 258 may be coupled to the flip-flops 230, 232, . . . , 234. The data bit signals, 260, 262, . . . 264 may be coupled to bit 0, 1, . . . , N of the (N+1) bit input data bus (DATA[N:0]) 252. The data bit signals, 260, 262, . . . 264 may be coupled to the flip-flops 230, 232, . . . , 234.

The (N+1) bit output control bus (CNTRL[N:0]) 250 may comprise the (N+1) stored value outputs 240, 242, . . . , 244 of the (N+1) flip-flops 230, 232, . . . , 234. When the load enable (LOAD) 254 is asserted, the reset (RESET) 258 is de-asserted, and the input clock (CLOCK) 256 transitions from a de-asserted state to an asserted state, the data values for the data bit signals, 260, 262, . . . 264 may be stored in the flip-flops 230, 232, . . . 244. The values stored in the flip-flops 230, 232, . . . 244 may be output on stored value outputs 240, 242, . . . , 244. When the reset (RESET) 258 is asserted, the values stored in the flip-flops 230, 232, . . . 244 may change to determined reset values. When the load enable (LOAD) 254 is de-asserted, and the reset (RESET) 258 is de-asserted, the values stored in the flip-flops 230, 232, . . . 244 may not change as a result of transitions of the input clock (CLOCK) 256 or the data bit signals, 260, 262, . . . 264.

The flip-flops 230, 232, . . . , 234 may comprise suitable circuitry, logic, and/or code and may be adapted to load and store a plurality of control or configuration values that may be used by the control block 200 or other functional blocks in the digital frequency divider.

The control block 208 may comprise suitable circuitry, logic, and/or code and may be adapted to store a plurality of control or configuration values, that may be presented on the output control bus 250, and that may be updated using the input data bus 252 when the load signal 254 is asserted for at least one cycle of the clock 256, and the reset 256 is de-asserted.

In operation, the flip-flops 230, . . . , 234 may be reset to a determined value by asserting the reset signal 258. When the reset signal 258 is de-asserted, the flip-flops 230, . . . , 234 may store a new value from the plurality of the data inputs 260, . . . 264 when the load signal 254 is asserted for one or more cycles of the clock 256. The plurality of the data inputs 260, . . . , 264, may comprise individual data bit values of the input data bus 252. When the reset signal 258 is de-asserted and the load signal 254 is de-asserted, the flip-flops 230, . . . , 234 may retain their stored values. The plurality of the control values 240, . . . , 244 stored by the flip-flops 230, . . . , 234 may be combined to create a plurality of output controls signals 250.

In instances. where N=2, in order to program the output control bus (CNTRL[N:0]) 250 with binary value 110, the input data bus (DATA[N:0]) 252 may be driven with binary value 110, the load enable (LOAD) 254 is asserted, and the reset (RESET) 258 is de-asserted. The data bit signal 260 may have a value of logic 0, the data bit signal 262 may have a value of logic 1, and the data bit signal 262 may have a value of logic 1. When the input clock (CLOCK) 256 transitions from a de-asserted state to an asserted state, the data values logic 0, logic 1, logic 1 on the data bit signals, 260, 262, . . . 264 may be stored in the flip-flops 230, 232, . . . 244.

The values stored in the flip-flops 230, 232, . . . 244 may be output on the stored value outputs 240, 242, . . . , 244. The stored value output 240 may have a value of logic 0, the stored value output 242 may have a value of logic 1, and the stored value output 244 may have a value of logic 1. The output control bus (CNTRL[N:0]) 250 may have a binary value of 110. When the reset (RESET) 258 is asserted, the values stored in the flip-flops 230, 232, . . . , 244 may change to determined reset values. When the load enable (LOAD) 254 is de-asserted, and the reset (RESET) 258 is de-asserted, the values stored in the flip-flops 230, 232, . . . 244 may not change as a result of transitions of the input clock (CLOCK) 256 or the data bit signals, 260, 262, . . . 264.

FIG. 3 is a block diagram of an exemplary digital frequency divider fixed counter block 202 of FIG. 2A, which may be utilized in accordance with an embodiment of the invention. Referring to FIG. 3, the fixed counter block 202 may comprise 2 flip-flops 310 and 312 and flip-flop 334. An input clock signal (CLK) 302 may be coupled to the flip-flop 310, and the flip-flop 334. A counter reset signal (CNTRST) 304 may be coupled to the flip-flops 310, 312, and 334. The stored value output 360 of the flip-flop 312 may be coupled to the data input of the flip-flops 334.

Inverted stored value outputs 320 and 322 of the flip-flops 310 and 312 may be coupled to data inputs of the flip-flops 310 and 312, respectively. The 2-bit count value (CNT[1:0]) 350 may comprise the 2 stored value outputs 340 and 342 of the 2 flip-flops 310 and 334. When the counter reset (CNTRST) 304 is de-asserted, and the input clock (CLK) 302 transitions from a de-asserted state to an asserted state, the data value for the data bit signal 360 may be stored in the flip-flop 334. The values stored in the flip-flops 310 and 334 may be output on the stored value outputs 340 and 342. When the counter reset (CNTRST) 304 is asserted, the value stored in the flip-flop 334 may change to determined reset values.

The 2 flip-flops 310 and 312 may comprise suitable circuitry, logic, and/or code and may be adapted to return to a determined reset value when the counter reset (CNTRST) 304 is asserted, and increment a 2-bit stored count value once per cycle of the clock (CLK) 302 when the counter reset 304 is de-asserted. The flip-flop 334 may comprise suitable circuitry, logic, and/or code and may be adapted to update a storage element once per cycle of the clock (CLK) 302 with the value output 360 that may comprise one bit of the 2-bit count value.

The fixed counter block 202 may comprise suitable circuitry, logic, and/or code and may be adapted to receive the clock (CLK) 302 and the counter reset (CNTRST) 304 inputs, and for each cycle of the clock (CLK) 302 where the counter reset (CNTRST) 304 is de-asserted, increment a count value presented on the counter output (CNT[1:0]) 350, and when the counter reset (CNTRST) 304 is asserted, present a determined reset value on the counter output (CNT[1:0]) 350.

In operation, the feedback 320 may connect the inverted output of the flip-flop 310 with the D input of the flip-flop 310. Therefore, for every cycle of the clock (CLK) 302, the stored value in the flip-flop 310, and thus the value of flip-flop output 360, may toggle between logic 0 and logic 1. Similarly, the feedback 322 may connect the inverted output of the flip-flop 312 with the D input of the flip-flop 312. Because the clock input of the flip-flop 312 may be coupled to the feedback 320, for every two cycles of the clock 302, the stored value in the flip-flop 312, and thus the value of the flip-flop output 362, may toggle between logic 0 and logic 1.

For 2 flip-flops 310 and 312 coupled in this fashion, the flip-flop outputs 340 and 360 form a counter value that may increment once per clock cycle, which may count through 4 values. The flip-flop 334 may update a storage elements once per cycle of the clock (CLK) 302 with the value of the output 360 that may comprise one bit of the 2-bit count value. When the counter reset (CNTRST) 304 is asserted, the values stored in the flip-flops 310 and 312 and the flip-flop 334 may return to a determined reset value that does not change with each cycle of the clock (CLK) 302.

FIG. 4 is a block diagram of an exemplary digital frequency divider fixed comparator block 204 of FIG. 2A, which may be utilized in accordance with an embodiment of the invention. Referring to FIG. 4, the fixed comparator block 204 may comprise XNOR gates 450, and 452, NAND gate 474, and flip-flop 486. An input clock signal (CLK) 402 may be coupled to the flip-flop 486. An input enable signal (ENABLE) 406 may be coupled to the flip-flop 486. The count value bit signals, 412, and 414 may be coupled to bit 0, and 1 the 2-bit input count value bus (CNT[1:0]) 410. The count value bit signals, 412 and 414 may be coupled to the XNOR gates 450, and 452.

The control word bit signals, 432 and 434 may be coupled to bit 1 and 2 of the 2-bit input control word bus (CNTRL[2:1]) 430. The control word bit signals, 432 and 434 may be coupled to the XNOR gates 450 and 452. The bit compare outputs, 462 and 464 of the XNOR gates 450 and 452 may be coupled to the inputs of the NAND gate 474. The two-bit compare output 480 of the NAND gate 474 may be coupled to the flip-flop 486. When the input clock (CLK) 402 transitions from a de-asserted state to an asserted state, the data value on the two-bit compare output 480 may be stored in the flip-flop 486, and may be an output (COMPCLK) of the fixed comparator block 204. The value stored in the flip-flop 486 may be output on the stored two-bit compare output 404. The compare result (RST) 404 may be coupled to the output of the flip-flop 486.

The XNOR gates 450 and 452 may comprise suitable circuitry, logic, and/or code and may be adapted to compare each bit of an 2-bit count value 410 with each bit of an 2-bit control value 430, and output a compare result signals 462 and 464 that are active when bit [X] of the count value (CNT) 410 are identical to bit [X+1] of the control value (CNTRL) 430, where 0<X<1.

The NAND gate 474 may comprise suitable circuitry, logic, and/or code and may be adapted to assert a reduced compare result signal 480 where the compare success output signal is asserted only if all of the compare result signals 462 and 464 are asserted. The flip-flop 486 may comprise suitable circuitry, logic, and/or code and may be adapted to store the final comparison result, updated once per cycle of the clock 402. When the input clock (CLK) 402 transitions from a de-asserted state to an asserted state, the storage element in the flip-flop 486 may be updated with the data values on the input 480. The values stored in the flip-flop 486 may be output on the flip-flop output 404. When the enable input is de-asserted, the RST input of the flip-flop 486 is asserted, and the storage element in flip-flop 486 return to a determined reset value.

The fixed comparator block 204 may comprise suitable circuitry, logic, and/or code and may be adapted to compare a 2-bit count value 410 with a 2-bit control value 430. If the 2-bit count value 410 and the 2-bit control value 430 are identical, the fixed comparator block 204 may transition a clock output (COMPCLK) 276 from a de-asserted state to an asserted state and may assert an output comparison result signal (RST) 404, that may be delayed by one or more cycles of the clock 402. Even though FIG. 4 illustrates a fixed comparator block 204 that generates an active-low comparison result signal (RST) 404, the invention may not be so limited. For example, in another embodiment, the result signal (RST) 404 may be coupled to the inverting output of the flip-flop 486 to generate an active-high comparison result signal (RST) 404.

In operation, 2 two-input XNOR gates 450 and 452 may compare bit M of the 2-bit count value (CNT) 410, with bit M+1 of the 2-bit control value (CNTRL) 430, where 2>M>0, to generate compare result signals 462 and 464. The result signals 462 and 464 may be coupled to the inputs of the two-input NAND gates 474 to generate a reduced compare result signal 480. The reduced compare result signal 480 may be registered by the flip-flop 486, to generate the registered reduced compare result signal 404, which is asserted when the 2-bit count value 410 and the 2-bit control value 430 are identical. A new comparison operation begins when there is a change in the 2-bit count value (CNT) 410 or the 2-bit control value (CNTRL) 430. The comparison result signal (RST) 404 may be updated once per cycle of the clock (CLK) 402.

For example, in operation, if the count value (CNT[1:0]) is binary value 10, and the control word (CNTRL[2:1]) is binary value 10, the two bit compare outputs, 462 and 464 of the two XNOR gates 450 and 452 are binary 11. The two-bit compare outputs, 462 and 464 are input to the NAND gate 474, and the compare output 480 of the NAND gate 474 is binary value 0. When the input clock (CLK) 402 transitions from a de-asserted state to an asserted state, the storage element in the flip-flops 486may be updated with the binary 0 data value on the input 480. The flip-flop 486 output with binary value of 0 may assert an active-low comparison result output (RST) 404.

For example, in operation, if the count value (CNT[1:0]) is binary value 00, and the control word (CNTRL[2:1]) is binary value 01, the two bit compare outputs, 462 and 464 of the two XNOR gates 450 and 452 are binary 10. The two-bit compare outputs, 462 and 464 are input to the NAND gate 474, and the compare output 480 NAND gate 474 is binary value 1. When the input clock (CLK) 402 transitions from a de-asserted state to an asserted state, the storage element in the flip-flops 486may be updated with the binary 1 data value on the input 480. The flip-flop- 486 output with binary value of 1 may de-assert an active-low comparison result output (RST) 404.

FIG. 5 is a block diagram of an exemplary digital frequency divider scalable counter block 270 of FIG. 2A, which may be utilized in accordance with an embodiment of the invention. Referring to FIG. 5, the scalable counter block 270 may comprise N−2 flip-flops 510, 512, . . . , 514, and N−2 flip-flops 530, 532, . . . , 534. An input clock signal (CLK) 502 may be coupled to the flip-flop 510, and the flip-flops 530, 532, . . . , 534. A counter reset signal (HICNTRST) 504 may be coupled to the flip-flops 510, 512, . . . , 514, and 530, 532, . . . , 534. The stored value outputs, 560, 562, . . . 564 of the flip-flops 520, 522, . . . 524 may be coupled to the data inputs of the flip-flops 530, 532, . . . , 534. Inverted stored value outputs 520, 522, . . . , 524 of the flip-flops 510, 512, . . . , 514 are coupled to data inputs of the flip-flops 510, 512, . . . , 514, respectively. The N−2 bit count value (CNT[N−1 :2]) 550 may comprise the N−2 stored value outputs 540, 542, . . . , 544 of the N−2 flip-flops 530, 532, . . . , 534.

In instances where the counter reset (HICNTRST) 504 is de-asserted, and the input clock (CLK) 502 transitions from a de-asserted state to an asserted state, the data values for the data bit signals, 560, 562, . . . 564 may be stored in the flip-flops 530, 532, . . . 544. The values stored in the flip-flops 530, 532, . . . 544 may be output on the stored value outputs 540, 542, . . . , 544. When the counter reset (HICNTRST) 504 is asserted, the values stored in the flip-flops 530, 532, . . . 544 may change to determined reset values.

The plurality of N−2 flip-flops 510, 512, . . . , 514 may comprise suitable circuitry, logic, and/or code and may be adapted to return to a determined reset value when the counter reset (HICNTRST) 504 is asserted, and increment an N−2 bit stored count value once per cycle of the clock (CLK) 502 when the counter reset 504 is de-asserted. The plurality of N−2 flip-flops 530, 532, . . . , 534 may comprise suitable circuitry, logic, and/or code and may be adapted to update N−2 bits of storage elements once per cycle of the clock (CLK) 502 with the values of the plurality of N−2 outputs 560, 562, . . . , 564, which may comprise the N−2 bit count value.

The scalable counter block 270 may comprise suitable circuitry, logic, and/or code and may be adapted to receive the clock (CLK) 502 and the counter reset (HICNTRST) 504 inputs, and for each cycle of the clock (CLK) 502 where the counter reset (HICNTRST) 504 is de-asserted, increment a count value presented on the counter output (CNT[N−1:2]) 550, and when the counter reset (HICNTRST) 504 is asserted, present a determined reset value on the counter output (CNT[N−1:2]) 550.

In operation, the feedback 520 may couple the inverted output of the flip-flop 510 with the D input of the flip-flop 510. Therefore, for every cycle of the clock (CLK) 502, the stored value in the flip-flop 510. Accordingly, the value of flip-flop output 560, may toggle between logic 0 and logic 1. Similarly, the feedback 522 may connect the inverted output of the flip-flop 512 with the D input of the flip-flop 512. Because the clock input of the flip-flop 512 may be coupled to the feedback 520, for every two cycles of the clock 502, the stored value in the flip-flop 512, and thus the value of the flip-flop output 562, may toggle between logic 0 and logic 1.

For a plurality of N−2 flip-flops 510, 512, . . . , 514 coupled in this fashion, the output 564 of the flip-flop 514 may toggle between logic 0 and logic 1 once every 2^{((N-2)-1)} clock cycles. For a plurality of N−2 flip-flops 510, 512, ... , 514 coupled in this fashion, N−2 flip-flop outputs 560, 562, ... , 564 form a counter value that may increment once per clock cycle, which may count through 2^{(N-2)} values. The plurality of N−2 flip-flops 530, 532, ... , 534 may update the N−2 bits of storage elements once per cycle of the clock (CLK) 502 with the values of the plurality of N−2 outputs 560, 562 . . . , 564 that may comprise the N−2 bit count value. When the counter reset signal (HICNTRST) 504 is asserted, the values stored in the flip-flops outputs 510, 512, . . . . 514 and the flip-flops 530, 532, . . . , 534 may return to a determined reset value that does not change with each cycle of the clock (CLK) 502.

FIG. 6 is a block diagram of an exemplary digital frequency divider scalable comparator block 272 of FIG. 2A, which may be utilized in accordance with an embodiment of the invention. Referring to FIG. 6, the scalable comparator block 272 may comprise XNOR gates 650, 652 . . . , 660, NAND gates 674, . . . , 678, flip-flop 686 and NOR gate 606. An input clock signal (CLK) 602 may be coupled to the flip-flop 686. An input reset signal (CNTRST) 690 may be coupled to the flip-flop 686. The count value bit signals, 612, 614, 616, 618, . . . , 620, 622 may be coupled to bit 2, 3, . . . . N−1 of the N−2 bit input count value bus (CNT[N−1:2]) 610. The count value bit signals, 612, 614, 616, 618, . . . , 620, 622 may be coupled to the XNOR gates 650, 652, 654, 656, . . . , 658, 660. The control word bit signals, 632, 634, 636, 638, . . . , 640, 642 may be coupled to bit 3, 4, . . . , N of the N−2 bit input control word bus (CNTRL[N:3]) 630. The control word bit signals, 632, 634, 636, 638, . . . , 640, 642 may be coupled to the XNOR gates 650, 652, 654, 656, . . . , 658, 660.

The bit compare outputs, 662, 664, 666, 668, . . . , 670, 672 of the XNOR gates 650, 652, 654, 656, . . . , 658, 660 may be coupled to the inputs of the NAND gates 674, 676, . . . , 678. The two-bit compare outputs 680, 682, . . . , 684 of the NAND gates 674, 676, . . . , 678 may be coupled to the NOR gate 606. The enable output 692 of NOR gate 606 may be coupled to the input of the flip-flop 686. When the input clock (CLK) 602 transitions from a de-asserted state to an asserted state, and when the reset input signal (CNTRST) is de-asserted, the data value of enable output 692 may be stored in the flip-flop 686. When reset input signal (CNTRST) is asserted, the stored value in flip-flop 686 returns to a determined reset value. The value stored in the flip-flop 686 may be output on the enable output (ENABLE) 604. The logic inverted value of the value stored in the flip-flop 686 may be output on the enable output signal (HICNTRST) 698.

The XNOR gates 650, . . . , 660 may comprise suitable circuitry, logic, and/or code and may be adapted to compare each bit of an N−2 bit count value 610 with each bit of an N−2 bit control value 630, and output a plurality of compare result signals 662, . . . , 672 that are active when bit [X] of the count value (CNT) 610 are identical to bit [X+1] of the control value (CNTRL) 630, where 2<X<N−1.

The NAND gates 674, 676, . . . , 678 may comprise suitable circuitry, logic, and/or code and may be adapted to assert a plurality of reduced compare result signals 680, 682 . . . , 684, where each compare success output signal is asserted only if all of a subset of the plurality of compare result signals 662, 664, 666, 668, . . . 670, 672 is asserted. Each of the compare result signals 662, 664, 666, 668, . . . 670, 672 may be used to determine at least one of the reduced compare result signals 680, 682, . . . 684. Even though FIG. 6 illustrates 2-input NAND gates 674, 676, . . . , 678, the invention may not be so limited. For example, 4-input NAND gates may be coupled to the outputs of the XNOR gates 650, 652, 654, 656, . . . , 658, 660, to yield an equivalent circuit. Because one 4-input NAND gate may replace two 2-input NAND gates, the number of inputs of the NOR gate 606 in the equivalent circuit may be reduced by a factor of two.

The NOR gate 606 may comprise suitable circuitry, logic, and/or code and may be adapted to assert an enable output signal 692 when all of the compare inputs 608 are asserted, and to otherwise de-assert the enable output signal 692.

The flip-flop 686 may comprise suitable circuitry, logic, and/or code and may be adapted to store a comparison result, updated once per cycle of the clock 602. When the input clock (CLK) 602 transitions from a de-asserted state to an asserted state, and when the reset input signal (CNTRST) 690 is de-asserted, the storage elements in the flip-flop 686 may be updated with the data values on the input 692. The value stored in the flip-flop 686 may be output on the flip-flop outputs 604. The logic inverted value stored in the flip-flops 686 may be output on the flip-flop inverting output 698. In instances where the reset input signal (CNTRST) 690 is asserted, the stored value in flip-flop 686 returns to a determined reset value.

The scalable comparator block 272 may comprise suitable circuitry, logic, and/or code and may be adapted to compare an N−2 bit count value 610 with an N−2 bit control value 630. In instances where the N−2 bit count value 610 and the N−2 bit control value 630 are identical, scalable comparator block 272 may be adapted to assert an output enable signal (ENABLE) 604 and an counter reset signal (HICNTRST) 698, that may be delayed by one or more cycles of the clock 602. Even though FIG. 6 illustrates a scalable comparator block 272 that generates an active-high output enable signal (ENABLE) 604, the invention may not be so limited. In an exemplary embodiment of the invention, the output enable signal (ENABLE) may be coupled to the inverting output of flip-flop 686 to generate an active-low output enable signal (ENABLE) 604. Even though FIG. 6 illustrates a scalable comparator block 272 that generates an active-low counter reset signal (HICNTRST) 698, the invention may not be so limited. For example, in another embodiment, the counter reset signal (HICNTRST) 698 may be coupled to the non-inverting output of flip-flop 686 to generate an active-high the counter reset signal (HICNTRST) 698.

In operation, a plurality of N−2 two-input XNOR gates 650, 652, 654, 656, . . . , 658, 660 may compare bit M of the N−2 bit count value (CNT) 610, with bit M+1 of the N−2 bit control value (CNTRL) 630, where N>M>2, to generate a plurality compare result signals 662, 664, 666, 668, . . . , 670, 672. Pairs of the plurality of result signals 662, 664, 666, 668, . . . , 670, 672 may be coupled to the inputs of (N−2)/2 two-input NAND gates 674, 676, . . . , 678, to generate a plurality of (N−2)/2 reduced compare result signals 680, 682, . . . , 684. The plurality of (N−2)/2 reduced compare result signals 680, 682, . . . , 684 may be inputs 608 to NOR gate 606. The enable output signal 692 of NOR gate 606 may be asserted when the N−2 bit count value 610 and the N−2 bit control value 630 are identical. The enable output signal 692 of the NOR gate 606 may be registered by the flip-flops 686 when the counter reset (CNTRST) 690 is de-asserted. The non-inverting output of flip-flop 686 may be coupled to the enable output signal (ENABLE) 604, and the inverting output of flip-flop 686 may be coupled to the counter reset output signal (HICNTRST) 698. A new comparison operation begins when there is a change in the N−2 bit count values (CNT) 610 or the N−2 bit control value (CNTRL) 630. The enable output signal (ENABLE) 604 and counter reset signal (HICNTRST) 698 may be updated once per cycle of the clock (CLK) 602.

In an exemplary embodiment of the invention, in instances where N=8, and the count value (CNT[N−1:2]) is binary value 011010, and the control word (CNTRL[N:3]) is binary value 011010, the six bit compare outputs, 662, 664, 666, 668, . . . 670, 672 of the six XNOR gates 650, 652, 654, 656, . . . , 658, 660 are binary 111111. The six bit compare outputs, 662, 664, 666, 668, . . . , 670, 672 are input to the three NAND gates 674, 676, . . . , 678, and the three two-bit compare outputs 680, 682, . . . , 684 of the NAND gates 674, 676, . . . , 678 are binary value 000. The three two-bit compare outputs 680, 682, . . . , 684 are inputs 608 to NOR gate 606, and a binary 1 is the output enable result 692. When the input clock (CLK) 602 transitions from a de-asserted state to an asserted state, and when the reset input signal (CNTRST) 690 is de-asserted, the storage element in the flip-flops 686may be updated with the binary 1 data value on the inputs 692. The flip-flop 686 non-inverting output drives a binary value of 1 onto the enable output signal (ENABLE) 604. The flip-flop 686 inverting output drives a binary value of 0 onto counter reset output signal (HICNTRST) 690.

In another exemplary embodiment of the invention, in instances where N=8, and the count value (CNT[N−1:2]) is binary value 000000, and the control word (CNTRL[N:3]) is binary value 010000, the six bit compare outputs, 662, 664, 666, 668, . . . 670, 672 of the six XNOR gates 650, 652, 654, 656, . . . , 658, 660 are binary 101111. The six bit compare outputs, 662, 664, 666, 668, . . . , 670, 672 are input to the three NAND gates 674, 676, . . . , 678, and the three two-bit compare outputs 680, 682, 684 of the NAND gates 674, 676, . . . , 678 are binary value 100. The three two-bit compare outputs 680, 682, . . . , 684 are inputs 608 to NOR gate 606, and a binary 0 is the output enable result 692. When the input clock (CLK) 602 transitions from a de-asserted state to an asserted state, and when the reset input (CNTRST) 690 is de-asserted, the storage element in the flip-flops 686may be updated with the binary 0 data value on the inputs 692. The flip-flop 686 non-inverting output drives a binary value of 0 onto enable output signal (ENABLE) 604. The flip-flop 686 inverting output drives a binary value of 1 onto counter reset output signal (HICNTRST) 690.

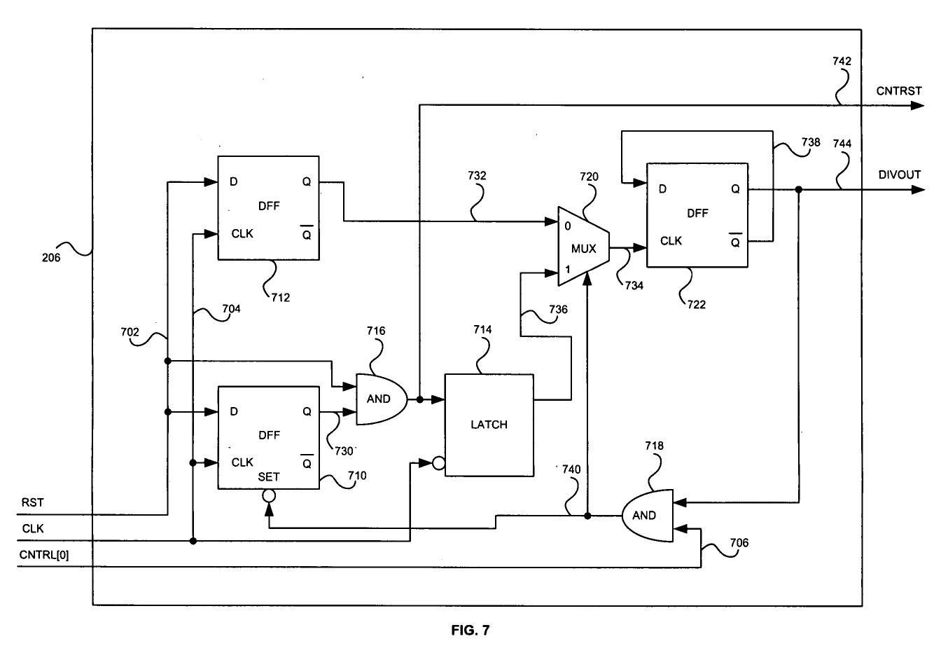

FIG. 7 is a block diagram of the exemplary digital frequency divider counter reset and output generation block 206 of FIG. 2A, which may be utilized in accordance with an embodiment of the invention. Referring to FIG. 7, the counter reset and output generation block 206 may comprise multiplexer 720, latch 714, AND gates 716 and 718, and flip-flops 710, 712, and 722. An input clock signal (CLK) 704 may be coupled to the flip-flops 710 and 712, and the latch 714. An input control bit signal (CTRL[0]) 706 may be coupled to the AND gate 718. An input reset signal (RST) 702 may be coupled to the AND gate 716, and the flip-flops 710 and 712.

The delayed reset 732 output of the flip-flop 712 may be coupled to the multiplexer 720. The delayed reset 730 output of the flip-flop 710 may be coupled to the AND gate 716. The counter reset output (CNTRST) 742 of the AND gate 716 may be coupled to the latch 714, and may be an output of the counter reset and output generation block 206. The pre-multiplexed clock 736 output from the latch 714 may be coupled to the multiplexer 720. The multiplexed clock 734 output from the multiplexer 720 may be coupled to the flip-flop 722. The inverting output 738 of the flip-flop 722 may be coupled to the data input of the flip-flop 722.

The counter reset output (CNTRST) 742 of the AND gate 716 may be coupled to the latch 714, and may be an output of the counter reset and output generation block 206. The frequency divided output (DIVOUT) 744 of the flip-flop 722 may be coupled to the AND gate 718, and may be an output of counter reset and output generation block 206. The odd division falling edge select 740 output of the AND gate 718 may be coupled to the multiplexer 720 and the flip-flop 710.

Even though FIG. 7 illustrates a circuit that accepts an active-low reset input (RST) 702, the invention may not be so limited. For example, the reset input (RST) 702 may be coupled to the input of an additional inverter, and the inverter output may be coupled to the D inputs of the flip-flops 712 and 710, and to the input of the AND gate 716, to create a circuit that accepts an active-high reset input (RST) 702. Somewhat similarly, even though FIG. 7 illustrates a circuit that may generate an active-low counter reset output (CNTRST) 742, the invention may not be so limited. For example, the AND gate 716 may be replaced with a NAND gate,. and the latch 714 may be replaced with a latch with an inverting output, to create a circuit that may generate. an active-high counter reset output (CNTRST) 742.

The flip-flop 712 may comprise suitable circuitry, logic, and/or code and may be adapted to store a single-bit logic value, updated once per cycle of the clock (CLK) 704 with the logic value of reset (RST) 702. The logic value of the storage element in the flip-flop 712 may be output on the delayed reset 732.

The flip-flop 710 may comprise suitable circuitry, logic, and/or code and may be adapted to store a single-bit logic value, updated once per cycle of the clock (CLK) 704 with the logic value of the reset (RST) 702 when the odd division falling edge select 740 is de-asserted. The logic value of the storage element in the flip-flop 710 may be set when the odd division falling edge select 740 is asserted. The logic value of the storage element in the flip-flop 710 may be output on the delayed reset 730.

The flip-flop 722 may comprise suitable circuitry, logic, and/or code and may be adapted to store a single-bit logic value, updated once per cycle of the multiplexed clock 734 with the inverted frequency divided output 738. The logic value of the storage element in the flip-flop 722 may be reflected on the output coupled to the frequency divided output (DIVOUT) 744. The inverse of the logic value of the storage element in the flip-flop 722 may be output on the inverted frequency divided output 738.

The latch 714 may comprise suitable circuitry, logic, and/or code and may be adapted to pass through the value of the counter reset (CNTRST) 742 to the pre-multiplexed clock 736 when the clock (CLK) 704 is de-asserted, and capture a value of the counter reset (CNTRST) 742 when the clock (CLK) 704 transitions from a de-asserted state to an asserted state. The latch 714 may comprise suitable circuitry, logic, and/or code and may be adapted to drive the said captured value of the counter reset (CNTRST) 742 to the pre-multiplexed clock 736 when the clock (CLK) 704 is asserted.

The AND gate 716 may comprise suitable circuitry, logic, and/or code and may be adapted to perform a logic AND of the reset (RST) 702 and the delayed reset 730. The result of the logic AND operation may be driven onto the counter reset (CNTRST) 742.

The AND gate 718 may comprise suitable circuitry, logic, and/or code and may be adapted to perform a logic AND of the control bit (CTRL[0]) 706 and the frequency divided output (DIVOUT) 744. The result of the logic AND operation may be driven onto the odd division falling edge select 740.

The multiplexer 720 may comprise suitable circuitry, logic, and/or code and may be adapted to pass through the delayed reset 732 to the multiplexed clock 734 when the odd division falling edge select 740 is de-asserted. The multiplexer 720 may comprise suitable circuitry, logic, and/or code and may be adapted to pass through the pre-multiplexed clock 736 to the multiplexed clock 734 when the odd division falling edge select 740 is asserted.

The counter reset and output generation block 206 may comprise suitable circuitry, logic, and/or code and may be adapted to generate the frequency divided output (DIVOUT) 744 and the counter reset signal (CNTRST) 742 using the reset (RST) 702, the clock (CLK) 704, and the control bit (CTRL[0]) 706. In instances where the control bit (CTRL[0]) 706 is de-asserted, the frequency divided output (DIVOUT) 744 is an even frequency division of clock (CLK) 704, and the multiplexer 720 may select the delayed reset 732 as the clock input to toggle the frequency divided output signal (DIVOUT) 744 of the flip-flop 722. When the control bit (CTRL[0]) 706 is asserted the frequency divided output signal (DIVOUT) 744 is an odd frequency division of the clock (CLK) 704. When the frequency divided output signa (DIVOUT) 744 is de-asserted, the multiplexer 720 may select the delayed reset 732 as the clock input to toggle the frequency divided output signal (DIVOUT) 744 of the flip-flop 722 from a de-asserted state to an asserted state. When the frequency divided output signal (DIVOUT) 744 is asserted, the multiplexer 720 may select the pre-multiplexed clock 736 as the clock input to toggle the frequency divided output signal (DIVOUT) 744 of the flip-flop 722 from an asserted state to a de-asserted state.

When the control bit (CTRL[0]) 706 is de-asserted, the frequency divided output (DIVOUT) 744 is an even frequency division of the clock (CLK) 704, the SET input of flip-flop 710 may be asserted, and therefore the delayed reset 730 may be asserted. The counter reset signal (CNTRST) 742 may be generated using a logic AND result of the asserted delayed reset 730 and the reset signal (RST) 702. Therefore the counter reset signal (CNTRST) 742 may be the reset (RST) 702 with a propagation delay introduced by the AND gate 716. When the control bit (CTRL[0]) 706 is asserted, and the frequency divided output (DIVOUT) 744 is de-asserted, the frequency divided output (DIVOUT) 744 is an odd frequency division of the clock (CLK) 704, the SET input of flip-flop 710 may be asserted, and therefore the delayed reset 730 may be asserted. The counter reset signal (CNTRST) 742 may be generated using a logic AND result of the asserted delayed reset 730 and the reset (RST) 702. Therefore the reset signal (CNTRST) 742 may be the reset (RST) 702 with a propagation delay introduced by the AND gate 716.

When the control bit (CTRL[0]) 706 is asserted and the frequency divided output (DIVOUT) 744 is asserted, the frequency divided output signal (DIVOUT) 744 is an odd frequency division of the clock (CLK) 704. The delayed reset 730 may be (RST) 702 with one clock cycle delay of (CLK) 704,, and therefore, the assertion of the counter reset signal (CNTRST) 742 occurs on the same clock cycle as the assertion of the reset signal (RST) 702 and the de-assertion of counter reset signal (CNTRST) 742 occurs on the clock cycle following the de-assertion of rest (RST) 702. Therefore, for odd frequency division, after M clock cycles, the counter reset signal (CNTRST) 742 may alternate between assertions of 1 clock cycle and 2 clock cycles in duration, where M is the value of bits [N:1] of the control word (CTRL[N:1]) 222 of control block 208.

In operation, referring to FIG. 7 and FIG. 2A, the reset input (RST) 702 is asserted when the fixed comparator block 204 detects that the count value (CNT[1:0]) 212 of fixed counter block 202 reaches the value specified in bits [2:1] of the control word (CTRL[N:1]) 222 of the control block 208, and when the scalable comparator block 272 detects that the count value (CNT[N−1:2]) 274 of the scalable counter block 270 reaches the value specified in bits [N:3] of the control word (CTRL[N:1]) 222 of the control block 208. The flip-flop 712 may be used to generate a delayed reset 732 from the reset input (RST) 702. When the control bit (CTRL[0]) 706 and the frequency divided output (DIVOUT) 744 are asserted, the frequency divided output (DIVOUT) 744 is an odd frequency division of the clock (CLK) 704 The odd division falling edge select 740, the flip-flop 710, the AND gate 716, and the latch 714 may be used to generate a pre-multiplexer clock 736 whose de-asserted state to asserted state transition is 180 degrees out of phase with the de-asserted state to asserted state transition of the delayed reset 732.

When the control bit (CTRL[0]) 706 is de-asserted, the frequency divided output (DIVOUT) 744 is an even frequency division of the clock (CLK) 704, and the delayed reset 732 may be used as the clock input to toggle the frequency divided output (DIVOUT) 744 of the flip-flop 722 between a de-asserted state and an asserted state.

When the control bit (CTRL[0]) 706 is asserted and the frequency divided output (DIVOUT) 744 is de-asserted, the frequency divided output (DIVOUT) 744 is an odd frequency division of the clock (CLK) 704.The delayed reset 732 may be used as the clock input to toggle the frequency divided output (DIVOUT) 744 of the flip-flop 722 from a de-asserted state to an asserted state. When the control bit (CTRL[0]) 706 is asserted and the frequency divided output (DIVOUT) 744 is asserted, the frequency divided output (DIVOUT) 744 is an odd frequency division of the clock (CLK) 704. The pre-multiplexed clock 736 may be used as the clock input to toggle the frequency divided output (DIVOUT) 744 of the flip-flop 722 from an asserted to a de-asserted state, which may allow for an approximately 50% duty cycle of frequency divided output (DIVOUT) 744 when odd frequency division of the clock (CLK) 704 is selected.

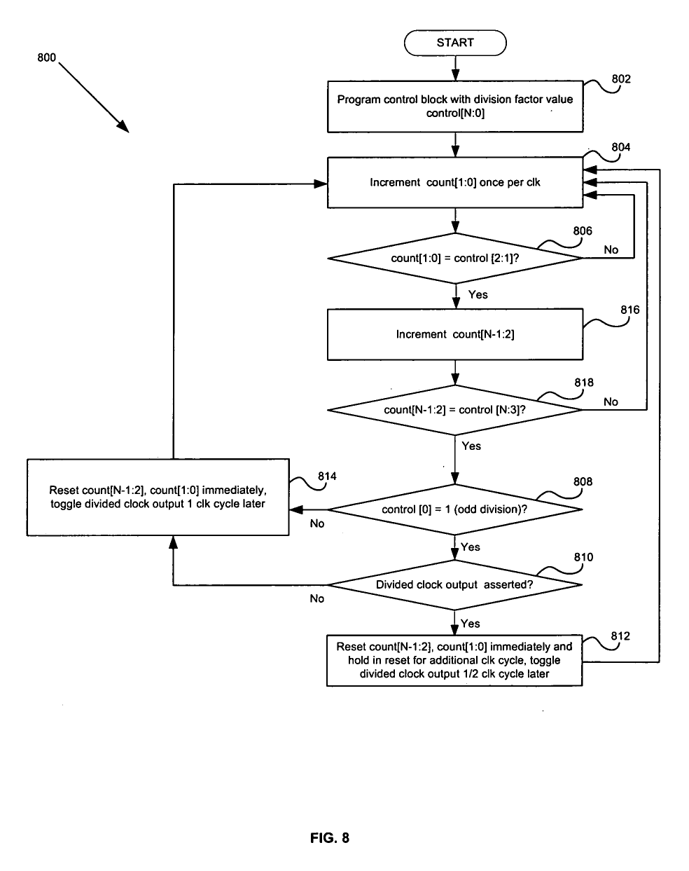

FIG. 8 is a flow diagram of exemplary steps for digitally generating frequency divided output signals, in accordance with an embodiment of the invention. Referring to FIG. 8, at step 802, bits N:0 of a (N+1) bit control word, control[N:0] may be configured with the frequency factor the input clock will be divided by to yield the output clock. At step 804, the fixed counter block count value, count[1:0], may be incremented once per clock cycle. At step 806, the comparator block may compare count[1:0] with control[2:1]. If the comparison fails because count[1:0] and control[2:1] are not equal, control passes back to step 804, where the fixed counter block count value may be incremented again. The comparison between count[1:0] with control[2:1] may be repeated, until the comparison succeeds, at which time control passes to step 816.

At step 816, the scalable counter block count value, count[N−1:2], may be incremented. At step 818, the scalable comparator block may compare count[N−1:2] with control[N:3]. If the comparison fails because count[N−1:2] and control[N:3] are not equal, control passes back to step 804, where the fixed counter block count value may be incremented again. The comparison between count[N−1:2] with control[N:3] may be repeated, until the comparison succeeds, at which time control passes to step 808.

At step 808, control block control[0] may be evaluated to determine whether the frequency division factor is odd or even. If control[0] is de-asserted, then the frequency division factor is even, and control passes to step 814. At step 814, the fixed counter and the scalable counter may be reset immediately, and the divided clock output may be toggled one clock cycle later. Control then passes back to step 804, where the counter block count value is incremented.

In step 808, if control[0] is asserted, then the frequency division factor is odd, and at 810, the divided clock output is checked to determined whether the divided clock output is asserted. In step 810, if the divided clock output is not asserted, control passes to step 814, where the fixed counter and the scalable counter may be reset immediately, and the divided clock output may be toggled one clock cycle later. In step 810, if the divided clock output is asserted, control passes to step 812. At step 812, the fixed counter and the scalable counter may be reset immediately and may be held in a reset state for an additional clock cycle, for total of two clock cycles, and the divided clock output may be toggled one-half clock cycle later, and control passes to step 804.

Referring to FIG. 2A, a lower-order bits count value (CNT[1:0]) 212 and a higher-order bits count value (CNT[N−1:2]) 274 may be generated based on a number of cycles of the input signal (CLK) 210. The generated higher-order bits count value (CNT[N−1:2]) 274 may be compared with the factor value (CNTRL[N:3]) 226 to generate an enable signal (ENABLE) 280 comprising a pipelined enable signal. When the enable signal (ENABLE) is asserted, the generated lower-order bits count value (CNT[1:0]) 212 may be compared with the factor value (CNTRL[2:1]) 222 to generate a match signal (RST) 214 comprising a pipelined match signal. The comparison may be performed utilizing a pipelined count value (CNT[1:0]) 212. An output signal resulting from the digital frequency dividing (DIVOUT) 216 may be toggled utilizing the match signal (RST) 214. The digital frequency dividing may be performed utilizing one comparator block 204 for handling lower-order bits, and one comparator block 272 for handling higher-order bits. The digital frequency dividing may also be performed utilizing one counter block such as the fixed counter block 202 for handling lower-order bits, and one counter such as the scalable counter block 270 for handling higher-order bits. Referring to FIG.7 one of two clock signals 732 and 736 may be selected and utilized to toggle the output signal (DIVOUT) 722. One bit of the factor value (CNTRL[0]) 706, and the output signal (DIVOUT) 722, may be utilized to select one of two clock signals 732 and 736.

Accordingly, aspects of the invention may be realized in hardware, software, firmware or a combination thereof. The invention may be realized in a centralized fashion in at least one computer system or in a distributed fashion where different elements are spread across several interconnected computer systems. Any kind of computer system or other apparatus adapted for carrying out the methods described herein is suited. A typical combination of hardware, software and firmware may be a general-purpose computer system with a computer program that, when being loaded and executed, controls the computer system such that it carries out the methods described herein.

One embodiment of the present invention may be implemented as a board level product, as a single chip, application specific integrated circuit (ASIC), or with varying levels integrated on a single chip with other portions of the system as separate components. The degree of integration of the system will primarily be determined by speed and cost considerations. Because of the sophisticated nature of modern processors, it is possible to utilize a commercially available processor, which may be implemented external to an ASIC implementation of the present system. Alternatively, if the processor is available as an ASIC core or logic block, then the commercially available processor may be implemented as part of an ASIC device with various functions implemented as firmware.

The present invention may also be embedded in a computer program product, which comprises all the features enabling the implementation of the methods described herein, and which when loaded in a computer system is able to carry out these methods. Computer program in the present context may mean, for example, any expression, in any language, code or notation, of a set of instructions intended to cause a system having an information processing capability to perform a particular function either directly or after either or both of the following: a) conversion to another language, code or notation; b) reproduction in a different material form. . However, other meanings of computer program within the understanding of those skilled in the art are also contemplated by the present invention.

While the invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiments disclosed, but that the present invention will include all embodiments falling within the scope of the appended claims.

What is claimed is:

1. A method for generating a signal, the method comprising digitally frequency dividing an input signal by a factor value specified as an N+1 bit value, utilizing a plurality of counters having a total of N bits.

2. The method according to claim 1, further comprising generating a single count value from said plurality of counters based on a number of cycles of said input signal.

3. The method according to claim 2, further comprising comparing said generated single count value with said factor value to generate a match signal.

4. The method according to claim 3, further comprising toggling an output signal from said digitally frequency dividing utilizing said match signal.

5. The method according to claim 3, further comprising performing said comparing utilizing a plurality of pipelined count values.

6. The method according to claim 3, wherein said match signal comprises a pipelined match signal.

7. The method according to claim 1, further comprising performing said digital frequency dividing utilizing at least one comparator for handling lower-order bits, and at least one comparator for handling higher-order bits.

8. The method according to claim 1, further comprising performing said digital frequency dividing utilizing at least one counter for handling lower-order bits, and at least one counter for handling higher-order bits.

9. The method according to claim 1, further comprising toggling an output signal from said digitally frequency dividing utilizing two clock signals.

10. The method according to claim 9, further comprising selecting one of said two clock signals to toggle said output signal utilizing one bit of said factor value.

11. The method according to claim 9, further comprising selecting one of said two clock signals to toggle said output signal utilizing said output signal.

12. The method according to claim 9, wherein said two clock signals are 180 degrees out of phase with respect to each other.

13. A system for generating a signal, the system comprising a digital frequency divider that divides an input signal by a factor value specified as an N+1 bit value, utilizing a plurality of counters having a total of N bits.

14. The system according to claim 13, further comprising circuitry that generates a single count value from said plurality of counters based on a number of cycles of said input signal.

15. The system according to claim 14, further comprising circuitry that compares said generated single count value with said factor value to generate a match signal.

16. The system according to claim 15, further comprising circuitry that toggles an output signal from said digitally frequency divider utilizing said match signal.

17. The system according to claim 15, further comprising circuitry that performs said comparing utilizing a plurality of pipelined count values.

18. The system according to claim 15, wherein said match signal comprises a pipelined match signal.

19. The system according to claim 13, further comprising circuitry that performs said digital frequency dividing utilizing at least one comparator for handling lower-order bits, and at least one comparator for handling higher-order bits.

20. The system according to claim 13, further comprising circuitry that performs said digital frequency dividing utilizing at least one counter for handling lower-order bits, and at least one counter for handling higher-order bits.

21. The system according to claim 13, further comprising circuitry that toggles an output signal from said digitally frequency divider utilizing two clock signals.

22. The system according to claim 21, further comprising circuitry that selects one of said two clock signals to toggle said output signal utilizing one bit of said factor value.

23. The system according to claim 21, further comprising circuitry that selects one of said two clock signals to toggle said output signal utilizing said output signal.

24. The system according to claim 21, wherein said two clock signals are 180 degrees out of phase with respect to each other.

25. A system for generating a signal, the system comprising:
a digital frequency divider comprising:
a 2-bit counter coupled to an input clock signal;
a 2-bit comparator coupled to an output of said 2-bit counter and input clock signal;
a N−2 bit counter coupled to an output of said 2-bit comparator;
a N−2 bit comparator coupled to an output of said 2-bit comparator and coupled to an output of said N−2 bit counter; wherein an output of said N−2 bit comparator is coupled to an input of said N−2 bit counter and wherein an output of said N−2 bit comparator is coupled to an input of said 2-bit comparator; a reset and output generator coupled to an output of said 2-bit comparator and said input clock signal, wherein an output of said reset and output generator is coupled to an input of said 2-bit counter; and
a controller coupled to an input of said N−2 bit comparator and an input of said 2-bit comparator and an input of said reset and output generator, wherein an output of said digital frequency divider is an output of said reset and output generator.

26. The system according to claim 25, wherein said reset and output generator comprises:
a first flip-flop;
a MUX coupled to an output of said first flip-flop, wherein said an output of said first flip-flop is coupled to a first input of said MUX;
a latch coupled to a second input of said MUX, wherein:
an output of a first AND gate is coupled to an first input of said latch, and is said output of said reset and output generator that is coupled to said input of said 2-bit counter and said input of N−2 bit comparator; and
a first input of said first AND gate is coupled to an output of a second flip-flop;
a second AND gate, wherein an output of said second AND gate is coupled to an input of said second flip-flop and a select of said MUX;
a third flip-flop, wherein:
a first input of said third flip-flop is coupled to an output of said MUX;
a first output of said third flip-flop is said output of said digital frequency divider that is said output of said reset and output generator, and is coupled to a first input of said second AND gate;
a second output of said third flip-flop is coupled to a second input of said third flip-flop; and
a second input of said second AND gate is coupled to at least a portion of an output of said controller; and
wherein:
said input clock signal is coupled to an input of said first flip-flop, and input of said second flip-flop, and input of said latch; and
said output of said 2-bit comparator is coupled to an input of said first flip-flop, and input of said second flip-flop, and a second input of said AND gate.

27. The system according to claim 25, wherein said N−2 bit counter is reset once per toggle of said output of said digital frequency divider.

28. The system according to claim 25, wherein said 2-bit counter is reset once per toggle of said output of said digital frequency divider.
